(19) United States
(12) Patent Application Publication
(10) Pub. No.: US 2019/0317358 A1
(43) Pub. Date: Oct. 17, 2019

(54) WINDOWS FOR DISPLAY DEVICES AND METHODS OF MANUFACTURING THE SAME AND DISPLAY DEVICES

(71) Applicant: Samsung Electronics Co., Ltd., Suwon-si (KR)

(72) Inventors: Du Seop YOON, Seongnam-si (KR); Ginam KIM, Seongnam-si (KR); Byung Ha PARK, Yongin-si (KR); Myong Jong KWON, Suwon-si (KR); Sung Hun HONG, Hwaseong-si (KR); Won Cheol JUNG, Seoul (KR)

(73) Assignee: Samsung Electronics Co., Ltd., Suwon-si (KR)

(21) Appl. No.: 16/136,529

(22) Filed: Sep. 20, 2018

(30) Foreign Application Priority Data
Apr. 12, 2018 (KR) 10-2018-0042874

(51) Int. Cl. G02F 1/1333; H01L 51/56; G02F 1/1339; G06F 3/041; H01L 51/52; H01L 51/00

(52) U.S. Cl. CPC G02F 1/133308; H01L 51/56; G02F 1/1339; G02F 2001/133331; H01L 51/5237; H01L 51/0017; G06F 3/0412

(57) ABSTRACT

A window for a display device includes a substrate and a functional layer applied on the substrate, wherein the window has surface irregularities, and the surface irregularities are associated with a depth histogram that has a positive skewness and a positive kurtosis. A method of manufacturing the same and a display device including the window are disclosed.

### CROSS-REFERENCE TO RELATED APPLICATION

This application claims priority to and the benefit of, under 35 U.S.C. § 119, Korean Patent Application No. 10-2018-0042874 filed in the Korean Intellectual Property Office on Apr. 12, 2018, the entire contents of which are incorporated herein by reference.

### BACKGROUND

### 1. Field

Windows for display devices, methods of manufacturing the same, and display devices are disclosed.

### 2. Description of the Related Art

A portable electronic device such as a smart phone or a tablet PC may include a window made of (“at least partially comprising”) a rigid glass or plastic for protecting a display module, and a functional layer having (“associated with”) the various functions is applied on a surface of the window.

However, recently, as a touch screen panel recognizing a contact position using a finger or a tool is universalized, the functional layer applied on the surface of the window may be easily worn down due to the frequent contacts of a user.

### SUMMARY

Some example embodiments provide a window for a display device, where the window is configured to have improve durability while satisfying optical properties.

Some example embodiments provide a method of manufacturing the window for a display device.

Some example embodiments provide a display device including the window for a display device.

According to some example embodiments, a window for a display device may include a substrate and a functional layer on the substrate. The window may include a plurality of surface irregularities. The plurality of surface irregularities may be associated with a depth histogram that has a positive skewness and a positive kurtosis.

The plurality of surface irregularities of the window may be associated with a plurality of surface irregularities of the substrate. The functional layer may be associated with the plurality of surface irregularities of the substrate.

An average surface roughness (Ra) and a mean spacing (Sm) of profile irregularities of the window may satisfy Relationship Formula 1:

Ra(nm)/Sm(μm)≤5.0 [Relationship Formula 1]

wherein, in Relationship Formula 1, Ra denotes an average surface roughness of the window, and Sm denotes a mean spacing of profile irregularities of the window.

The average surface roughness (Ra) of the window may satisfy about 5 nm Ra≤about 60 nm.

The mean spacing (Sm) of profile irregularities of the window may satisfy about 5 μm≤Sm≤about 50 μm.

The average surface roughness (Ra) and the mean spacing (Sm) of profile irregularities of the window may satisfy Relationship Formula 2a:

Ra(nm)≤(10−α)/2.0529×Sm(μm) [Relationship Formula 2a]

wherein, in Relationship Formula 2a, Ra denotes an average surface roughness of the window, Sm denotes a mean spacing of profile irregularities of the window, and −3.6≤σ<0.

The average surface roughness (Ra) and the mean spacing (Sm) of profile irregularities of the window satisfy Relationship Formula 2c:

Ra(nm)≤(1−α)/2.0529×Sm(μm) [Relationship Formula 2c]

wherein, in Relationship Formula 2c, Ra denotes an average surface roughness of the window, Sm denotes a mean spacing of profile irregularities of the window, and −3.6≤α≤0.

The depth histogram may include a peak of between about 0 nm and about −100 nm.

The window may be associated with a haze of less than or equal to about 10.0.

The window may be associated with a variation ratio of a surface contact angle of less than or equal to about 40% after 20,000 cycles of abrasion rubbing test using 500 g eraser.

The substrate may be a glass substrate.

The substrate may be an etched glass substrate.

The functional layer may include an anti-fingerprint layer, an anti-reflection layer, an anti-glare layer, an anti-fouling layer, an anti-bacterial layer, a sub-combination thereof, or a combination thereof.

According to some example embodiments, a display device may include a display panel and the window.

The display panel may be an organic light emitting display panel or a liquid crystal display panel.

The display device may further include a touch screen panel between the display panel and the window.

According to some example embodiments, a method of manufacturing a window for a display device may include forming a plurality of surface irregularities on a substrate, and forming a functional layer on the substrate having the plurality of surface irregularities. The forming of surface irregularities may include performing primary etching of the substrate subsequently to masking the surface thereof, and performing secondary etching of the primary-etched substrate based on supplying a strong acid thereto. The plurality of surface irregularities of the substrate may be associated with a depth histogram that has a positive skewness and a positive kurtosis.

The secondary etching may be performed longer than the primary etching.

The forming of the functional layer may be performed based on a solution process or a deposition.

### BRIEF DESCRIPTION OF THE DRAWINGS

FIG. 1 is a cross-sectional view of a window for a display device according to some example embodiments,

FIG. 2 is a schematic view illustrating a definition of an average surface roughness of surface irregularities,

FIG. 3 is a schematic view illustrating a definition of a mean spacing of profile irregularities of surface irregularities,

FIG. 4 is a cross-sectional view of a display device according to some example embodiments,

FIG. 5 is a cross-sectional view of a display device according to some example embodiments,

FIG. 6 is a photograph showing a surface morphology of a window for a display device according to Example 1,

FIG. 7 is a photograph showing a surface morphology of a window for a display device according to Example 2,

FIG. 8 is a photograph showing a surface morphology of a window for a display device according to Example 3,

FIG. 9 is a photograph showing a surface morphology of a window for a display device according to Comparative Example 1,

FIG. 10 is a photograph showing a surface morphology of a window for a display device according to Comparative Example 2,

FIG. 11 is a photograph showing a surface morphology of a window for a display device according to Comparative Example 3,

FIGS. 12 to 16 are depth histogram graphs of windows for a display device according to Examples 1 to 3 and Comparative Examples 2 and 3, respectively,

FIG. 17 is a graph showing a surface contact angle change depending upon the cycles of abrasion resistance of the windows for a display device according to Examples 1, 2 and Comparative Examples 1 to 3, and

FIG. 18 is a graph showing a surface contact angle change depending upon the cycles of abrasion resistance of the windows for a display device according to Example 3 and Comparative Example 1.

### DETAILED DESCRIPTION

Example embodiments of the present disclosure will hereinafter be described in detail, and may be easily performed by a person having an ordinary skill in the related art. However, actually applied structures may be embodied in many different forms, and is not to be construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

Hereinafter, ‘combination’ refers to a mixture of two or more and a stack structure of two or more.

Hereinafter, a window for a display device according to some example embodiments is described.

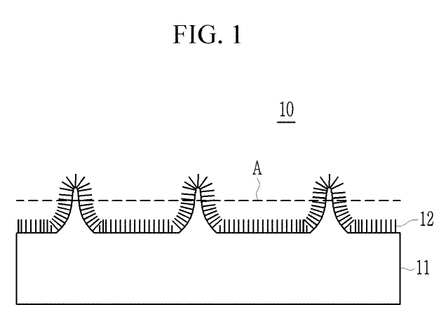

FIG. 1 is a cross-sectional view of a window for a display device according to some example embodiments.

Referring to FIG. 1, a window 10 for a display device according to some example embodiments has (“includes”) surface irregularities (“a plurality of surface irregularities”) and includes a substrate 11 and a functional layer 12 on the substrate 11.

The substrate 11 may be for example a glass substrate or a polymer substrate. The polymer substrate may include for example polyimide, polyamide, polyamideimide, polyethyleneterephthalate, polyethylenenaphthalene, polymethylmethacrylate, polycarbonate, a copolymer thereof, or a combination thereof, but is not limited thereto. For example, the substrate 11 may be a glass substrate.

Surface irregularities may be formed on one surface of the substrate 11, and surface irregularities of the window 10 for a display device may be derived from (“may be associated with”) the surface irregularities of the substrate 11. The surface irregularities of the substrate 11 may be a surface texture formed based on removing a part of the surface of the substrate 11 by a chemical and/or physical treatment. The chemical treatment may include, for example, etching by a chemical solution, and the physical treatment may include, for example, a mechanical friction, but is not limited thereto. For example, the substrate 11 may be an etched glass substrate.

As shown in FIG. 1, surface irregularities may include a plurality of bumps and a plurality of valleys which are repeatedly disposed. The bump and the valley may be disposed up and down in a center of a mean line A, and depths from the bump and from the valley are each a distance from the mean line A.

The functional layer 12 may cover the surface irregularities of the substrate 11. The functional layer 12 is formed in a thin thickness and is coated along with a shape of surface irregularities of the substrate 11, so the surface of the functional layer 12 may be also formed along with the dumps and the valleys. Accordingly, and as shown in at least FIG. 1, the functional layer 12 may be understood to be associated with the surface irregularities of the substrate 11. For example, the functional layer 12 may have a thickness of less than or equal to about 10 nm, for example, a thickness of about 1 nm to about 10 nm. The functional layer 12 may include for example an anti-fingerprint layer, an anti-reflection layer, an anti-glare layer, an anti-fouling layer, an anti-bacterial layer, a sub-combination thereof, or a combination thereof, but is not limited thereto.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

When a user touches the surface of the window 10 for a display device, the window 10 for a display device having surface irregularities may have different stress and area of the main contact surface from the window for a display device having no surface irregularities.

For example, when the user touches a surface of the window 10 for a display device, the contact surface contacted with the user may be mostly bumps which protrude from the surface of the window 10 for a display device, so the area of the contact surface may be reduced comparing to the case having no surface irregularities. Thereby, the overall abrasion resistance of the functional layer 12 of the window 10 for a display device may be enhanced.

On the other hand, the contact surface contacted with a user is focused onto the bump regions which protrude from the surface of the window 10 for a display device may increase the stress of the bump regions, so as to reduce the abrasion resistance of the bump regions of the functional layer 12 of the window 10 for a display device.

Thus the area and the stress of the contact surface may be controlled by adjusting a distribution of surface irregularities of the window 10 for a display device to improve the overall abrasion resistance of the functional layer 12.

For example, the distribution of the surface irregularities may be defined as a depth histogram, such that the plurality of surface irregularities may be understood to be associated with the depth histogram. In the depth histogram, when the mean line A is 0, the bump has a positive depth, which is a depth of greater than 0, and the valley has a negative depth, which is a depth of less than 0.

The depth histogram may be shown by skewness and kurtosis.

The skewness means an index showing how the surface irregularities are asymmetric, which may express the depth distribution and the numbers of bumps and valleys. For example, when average depths of bumps and valleys refer to a base line, a skewness may be 0 in the case that the numbers and the depths of bumps and valleys are symmetric; the skewness may be positive in the case that the depth distribution and the number of valleys is greater than the depth distribution and the number of bumps, that is, in the case that the main distribution is tilted to a left side in a center of a peak in the depth histogram graph; and the skewness may be negative in a case that the depth distribution and the number of bumps are greater than the depth distribution and the number of valley, that is, in the case that the main distribution is tilted to a right side in a center of a peak in the depth histogram graph.

The window 10 for a display device according to some example embodiments may have a positive skewness, so the depth distribution and the number of valleys may be greater than the depth distribution and the number of valleys. For example, surface irregularities of the window 10 for a display device may have a peak of the depth histogram within 0 nm to about −100 nm. Restated, the depth histogram with which the surface irregularities are associated may include a peak of between about 0 nm and about −100 nm.

The kurtosis is an index showing how is focused at a depth of the surface irregularities within a predetermined range, which may show how sharp the depth histogram graph is. For example, with a base line of a mean depth of bump and valley, when the kurtosis is 0 (reference) in a case that both the numbers and the depths of bumps and valleys are symmetric; the kurtosis may be positive in a case that the main distribution is sharper than the reference in a center of a peak in the depth histogram graph; and the kurtosis may be negative in a case that the main distribution is smoother than the reference in a center of a peak in the depth histogram graph.

The window 10 for a display device according to some example embodiments may have (“may be associated with”) a positive kurtosis, thus may be focused on a center of the peak at the depth histogram graph.

The skewness and the kurtosis may be obtained by sampling predetermined line profile (e.g., 120 μm×11 lines) from the surface morphology measured by, for example, a 3D microscope (Bruker, ContourGT) to measure a depth distribution and inputting the depth distribution to a statistics program (MINITAB).

As in above, as the depth histogram of the surface irregularities of the window 10 for a display device according to some example embodiments has a positive skewness and a positive kurtosis, the overall abrasion resistance of the functional layer 12 may be improved by (“based on”) controlling the area and the stress of the contact surface of the user.

For example, the distribution of surface irregularities may be expressed as an average surface roughness (Ra) and a mean spacing (Sm) of profile irregularities.

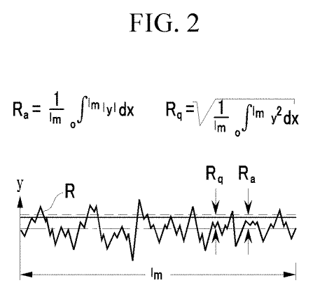

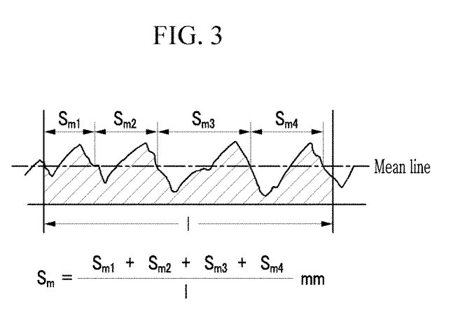

FIG. 2 is a schematic view describing a definition of an average surface roughness of the surface irregularities; and FIG. 3 is a schematic view describing a mean spacing of profile irregularities of surface irregularities.

Referring to FIGS. 2 and 3, the average surface roughness (Ra) may be an average difference of the surface texture, which is an average of the absolute value of the depth difference of bumps and valleys; and the mean spacing (Sm) of profile irregularities may be an average distance between bumps. For example, the average surface roughness (Ra) and the mean spacing (Sm) of profile irregularities may be measured by a 3D microscope (Bruker, ContourGT).

For example, the average surface roughness (Ra) and the mean spacing (Sm) of profile irregularities of the window 10 for a display device may satisfy the following Relationship Formula 1.

Ra(nm)/Sm(μm)≤5.0 [Relationship Formula 1]

In Relationship Formula 1,

Ra denotes an average surface roughness, and

Sm denotes a mean spacing of profile irregularities.

For example, the average surface roughness (Ra) of the window 10 for a display device may satisfy, for example, about 5 nm≤Ra≤about 100 nm, within the range, for example, about 5 nm≤Ra≤about 80 nm, about 5 nm≤Ra≤about 70 nm, about 5 nm≤Ra≤about 60 nm, about 5 nm≤Ra≤about 50 nm, about 10 nm≤Ra≤about 80 nm, about 10 nm≤Ra≤about 70 nm, about 10 nm≤Ra≤about 60 nm, or about 10 nm≤Ra≤about 50 nm.

For example, the mean spacing (Sm) of profile irregularities of the window 10 for a display device may satisfy, for example, about 5 μm≤Sm≤about 100 μm, within the range, may satisfy, for example, about 5 μm≤Sm≤about 90 μm, about 5 μm≤Sm about 80 μm, about 5 μm≤Sm≤about 70 μm, about 5 μm≤Sm≤about 60 μm, or about 5 μm≤Sm≤about 50 μm.

For example, the average surface roughness (Ra) and the mean spacing (Sm) of profile irregularities of the window 10 for a display device may be controlled relating to optical properties of the window 10 for a display device.

For example, the average surface roughness (Ra) and the mean spacing (Sm) of profile irregularities of the window 10 for a display device may satisfy Relationship Formula 2.

Ra(nm)≤(Hz−α)/2.0529×Sm(μm) [Relationship Formula 2]

In Relationship Formula 2,

Ra denotes an average surface roughness of a window for a display device,

Sm denotes a mean spacing of profile irregularities of a window for a display device,

−3.6≤α<0, and

Hz denotes a maximum value of a desirable haze.

For example, a haze of the window 10 for a display device may be about 10 or less (“the window may be associated with a haze of less than or equal to about 10.0”), wherein the average surface roughness (Ra) and the mean spacing (Sm) of profile irregularities of the window 10 for a display device may satisfy Relationship Formula 2a.

Ra(nm)≤(10−α)/2.0529×Sm(μm) [Relationship Formula 2a]

In Relationship Formula 2a,

Ra denotes an average surface roughness of a window for a display device,

Sm denotes a mean spacing of profile irregularities of a window for a display device, and

−3.6≤α<0.

For example, a haze of the window 10 for a display device may be about 5 or less, wherein the average surface roughness (Ra) and the mean spacing (Sm) of profile irregularities of the window 10 for a display device may satisfy Relationship Formula 2b.

Ra(nm)≤(5−α)/2.0529×Sm(μm) [Relationship Formula 2b]

In Relationship Formula 2b,

Ra denotes an average surface roughness of a window for a display device,

Sm denotes a mean spacing of profile irregularities of a window for a display device, and

−3.6≤α<0.

For example, a haze of the window 10 for a display device may be about 1 or less, wherein the average surface roughness (Ra) and the mean spacing (Sm) of profile irregularities of the window 10 for a display device may satisfy Relationship Formula 2c.

Ra(nm)≤(1−α)/2.0529×Sm(μm) [Relationship Formula 2c]

In Relationship Formula 2c,

Ra denotes an average surface roughness of a window for a display device,

Sm denotes a mean spacing of profile irregularities of a window for a display device, and

−3.6≤α<0.

By controlling the depth histogram of surface irregularities of the window 10 for a display device as in above, the abrasion resistance of the functional layer 12 may be enhanced. The abrasion resistance of the functional layer 12 may be evaluated by the surface characteristic change of the functional layer 12. For example, it may be evaluated from the surface contact angle of the functional layer 12 when physical frictions have been applied on the surface of the window 10 for a display device for a plurality of times. For example, after rubbing the surface of the window 10 for a display device with 500 g eraser for 20,000 cycles, the window 10 for a display device may have a variation ratio of a surface contact angle of less than or equal to about 40%.

The window 10 for a display device may be obtained in a variety of ways.

For example, the window 10 for a display device may be obtained by forming surface irregularities on a substrate and forming a functional layer 12 on the substrate 11 having the surface irregularities.

The substrate may be, for example, a glass substrate.

Surface irregularities may be formed by chemical and/or physical treatment, for example, it may be etched by a chemical solution or the surface may be removed by mechanical friction, but is not limited thereto.

For example, surface irregularities may be obtained by etching for a plurality of times, for example, it may include performing a primary etching after masking the surface of the substrate and performing a secondary etching based on supplying a strong acid onto the primary-etched substrate. The strong acid may be, for example, hydrofluoric acid, but is not limited thereto. For example, the primary etching may include dipping the substrate into a hydrofluoric acid solution after masking the surface of the substrate with a mask in a size of about 5 μm to form a fundamental irregularity morphology; and the secondary etching may finely control a gap between irregularities and a height distribution by dipping the same into a hydrofluoric acid solution after removing the mask. For example, the primary etching and the secondary etching are each independently performed for 30 seconds to 10 minutes. For example, the secondary etching may be performed longer than the primary etching.

For example, the functional layer 12 may be obtained by supplying organic, inorganic, or organic/inorganic material on a surface of the etched substrate 11 according to, for example, a solution process such as a spin coating, an inkjet, a slit coating, a bar coating or a dipping or deposition (evaporation), but is not limited thereto.

The window for a display device may be applied to various electronic devices. The electronic devices may be display devices, for example liquid crystal displays (LCD) or organic light emitting displays (OLED), but are not limited thereto.

The window for a display device may be attached on the display panel. Herein, the display panel and the window for a display device may be directly bonded or may be bound by interposing an adhesive or a tackifier.

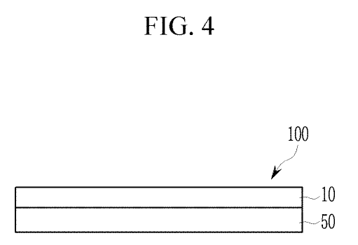

FIG. 4 is a cross-sectional view of a display device according to some example embodiments.

Referring to FIG. 4, a display device 100 according to some example embodiments includes a display panel 50, a window 10 for a display device, and optionally an adhesion layer (not shown).

The display panel 50 may be for example an organic light emitting display panel or a liquid crystal display panel.

The window 10 for a display device may be disposed on the side of an observer and the structure is the same as described above.

The display panel 50 and the window 10 for a display device may be bonded by the adhesion layer. The adhesion layer may include a tackifier or an adhesive, for example optical clear adhesive (OCA). The adhesion layer may be omitted.

Another layer may be interposed between the display panel 50 and the window 10 for a display device. For example, a monolayer or plural layers of polymer layer (not shown) and optionally a transparent adhesion layer (not shown) may be further included.

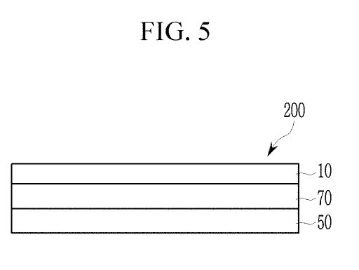

FIG. 5 is a cross-sectional view of a display device according to some example embodiments.

Referring to FIG. 5, the display device 200 according to some example embodiments includes a display panel 50, a window 10 for a display device, and a touch screen panel 70 disposed between the display panel 50 and the window 10 for a display device.

The display panel 50 may be for example an organic light emitting display panel or a liquid crystal display panel.

The window 10 for a display device may be disposed on the side of an observer and the structure is the same as described above.

The touch screen panel 70 may be disposed adjacent to each of the window 10 for a display device and the display panel 50 to recognize the touched position and the position change when is touched by a human hand or a tool through the window 10 for a display device and then to output a touch signal. The driving module (not shown) may monitor a position where is touched from the output touch signal; recognize an icon marked at the touched position; and control to carry out functions corresponding to the recognized icon, and the function performance results are displayed on the display panel 50.

Another layer may be interposed between the touch screen panel 70 and the window 10 for a display device. For example, a monolayer or plural layers of polymer layer (not shown) and optionally a transparent adhesion layer (not shown) may be further included.

The display device may be applied to a variety of electronic devices such as a smart phone, a tablet PC, a camera, a touch screen device, and so on, but is not limited thereto.

Hereinafter, some example embodiments are illustrated in more detail with reference to examples. However, the present disclosure is not limited to these examples.

### Fabrication of Window for Display Device

### Example 1

A glass substrate is washed with acetone, alcohol, and ultra pure water in an ultrasonic washer. Subsequently, the glass substrate is dried, and polystyrene particles (Sigma-Aldrich, Latex beads from PS, std dev <0.1 μm) are coated on the dried glass substrate. Subsequently, the polystyrene particle-coated glass substrate is input into a 5 times-diluted hydrofluoric acid aqueous solution (Sigma-Aldrich, 38% HF in H₂O) and subjected to a primary etching for 120 seconds. Surface irregularities are obtained by the primary etching, and it is input into a 10 times-diluted hydrofluoric acid aqueous solution (Sigma-Aldrich, 38% HF in H₂O) in order to minutely adjust a surface roughness (Ra) of surface irregularities and a mean spacing (Sm) of profile irregularities and subjected to a secondary etching for 160 seconds. AF coating (Daikin, UD509) is carried out on the etched glass substrate by a vacuum deposition after the secondary etching.

### Example 2

A window for a display device is obtained in accordance with the same procedure as in Example 1, except that the primary etching and the secondary etching are performed for 120 seconds and for 180 seconds, respectively.

### Example 3

A window for a display device is obtained in accordance with the same procedure as in Example 1, except that the primary etching and the secondary etching are performed for 180 seconds and for 240 seconds, respectively.

### Comparative Example 1

An anti-reflection coating liquid (UD509, Daikin) is spin-coated on un-etched flat glass substrate and dried to provide a functional layer having a thickness of less than or equal to 10 nm, so a window for a display device is obtained.

### Comparative Example 2

A window for a display device is obtained in accordance with the same procedure as in Example 1, except that the primary etching and the secondary etching are each performed for 120 seconds.

### Comparative Example 3

A window for a display device is obtained in accordance with the same procedure as in Example 1, except that the primary etching and the secondary etching are performed for 180 seconds and for 120 seconds, respectively.

### Evaluation

### Evaluation I

The windows for a display device according to Examples 1 to 3 and Comparative Examples 1 to 3 are observed for a surface morphology.

The surface morphology is observed using an optical microscope (LV100NPOL, NIKON).

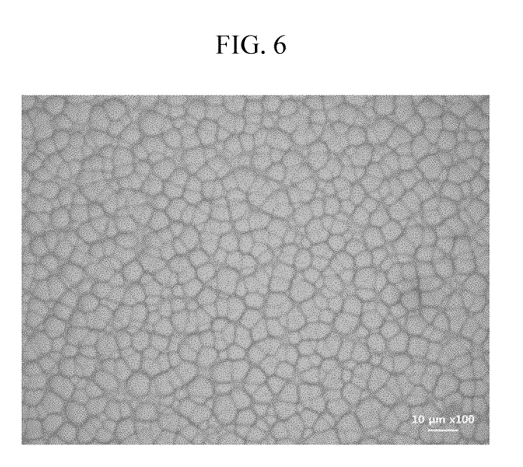

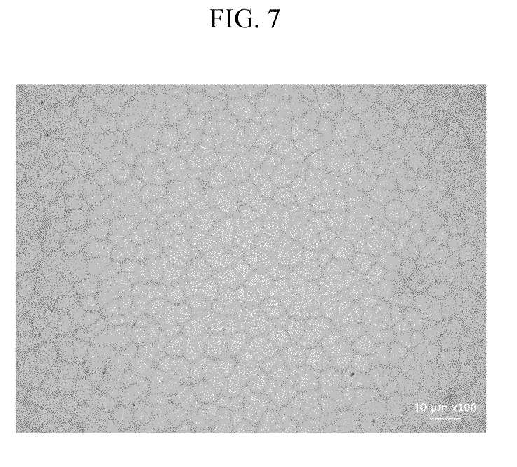

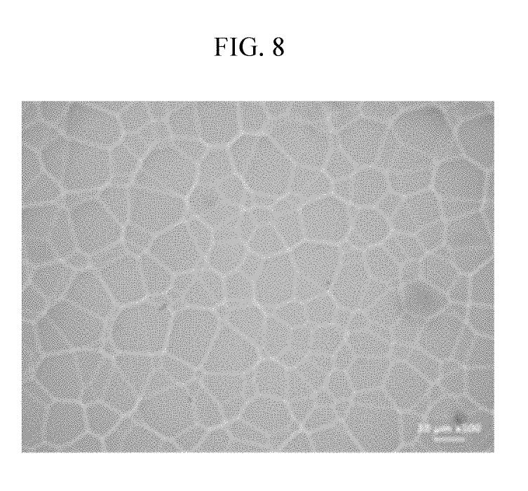

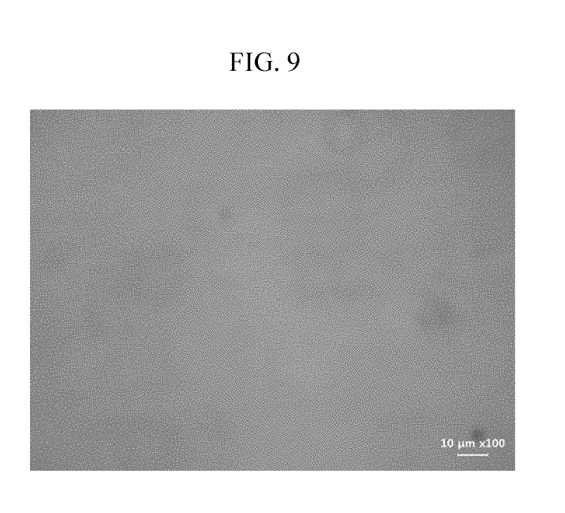

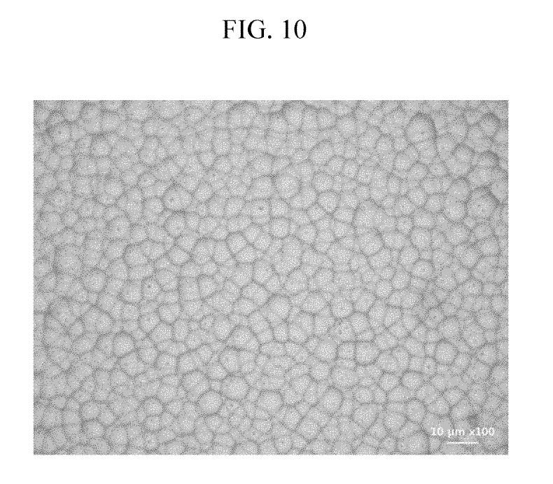

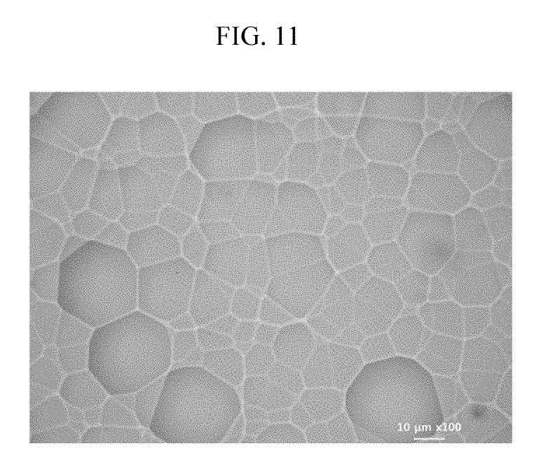

FIG. 6 is a photograph showing the surface morphology of the window for a display device according to Example 1; FIG. 7 is a photograph showing the surface morphology of the window for a display device according to Example 2; FIG. 8 is a photograph showing the surface morphology of the window for a display device according to Example 3; FIG. 9 is a photograph showing the surface morphology of the window for a display device according to Comparative Example 1; FIG. 10 is a photograph showing the surface morphology of the window for a display device according to Comparative Example 2; and FIG. 11 is a photograph showing the surface morphology of the window for a display device according to Comparative Example 3.

### Evaluation II

The windows for a display device according to Examples 1 to 3 and Comparative Examples 2 and 3 are evaluated for a depth histogram.

The depth histogram is measured by sampling a line profile (120 μm×11 lines) from the surface morphology measured by a 3D microscope (Bruker, ContourGT).

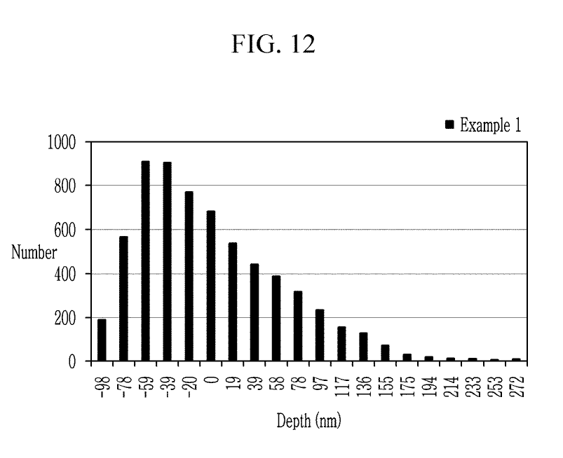

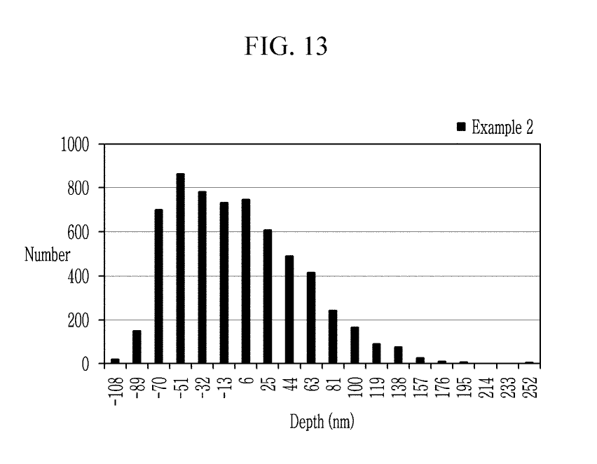

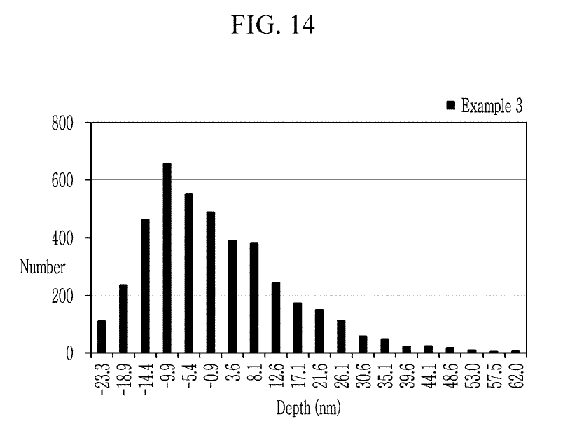

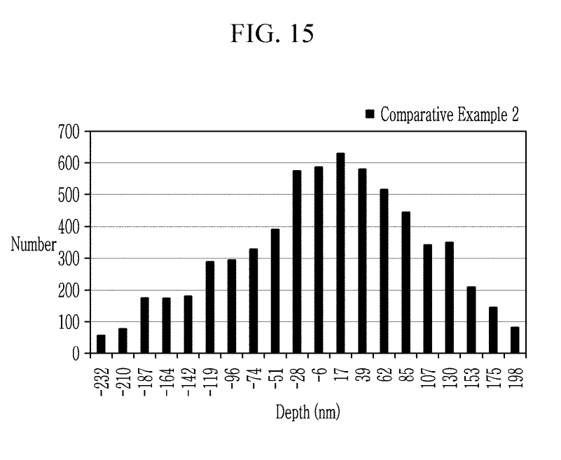

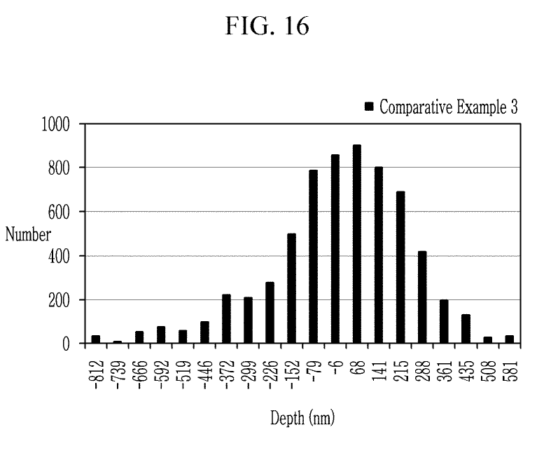

The depth histogram of the window for a display device is as shown in FIGS. 12 to 16 and Table 1.

FIGS. 12 to 16 are depth histogram graphs of the windows for a display device according to Examples 1 to 3 and Comparative Examples 2, 3, respectively.

TABLE 1

| | Skewness | Kurtosis |
|---|---|---|
| Example 1 | 0.91 | 0.69 |
| Example 2 | 0.70 | 0.34 |
| Example 3 | 0.92 | 0.92 |
| Comparative Example 2 | −0.24 | −0.52 |
| Comparative Example 3 | −0.66 | 0.85 |

Referring to FIGS. 12 to 16 and Table 1, it is confirmed that the depth histogram of the windows for a display device according to Examples 1 to 3 show a positive skewness and a positive kurtosis, on the other hand, the window for a display device according to Comparative Example 2 shows a negative skewness and a negative kurtosis, and the window for a display device according to Comparative Example 3 shows a negative skewness and a positive kurtosis.

### Evaluation III

The windows for a display device surface according to Examples 1 to 3 and Comparative Examples 2 and 3 are evaluated for an average surface roughness (Ra) and a mean spacing (Sm) of profile irregularities.

The average surface roughness (Ra) and the mean spacing (Sm) of profile irregularities are evaluated using a 3D microscope (ContourGT, Bruker) (average: 120 μm×10 μm).

The results are shown in Table 2.

TABLE 2

| | Ra (nm) | Sm (μm) | Ra(nm)/Sm(μm) |
|---|---|---|---|
| Example 1 | 57.5 | 12.4 | 4.6 |
| Example 2 | 47.7 | 12.4 | 3.8 |
| Example 3 | 19.0 | 32.0 | 0.6 |
| Comparative Example 2 | 72.4 | 11.4 | 6.4 |
| Comparative Example 3 | 214.0 | 35.2 | 6.1 |

Referring to Table 2, it is confirmed that the window for a display device according to Example has less a ratio of the average surface roughness (Ra) and the mean spacing (Sm) of profile irregularities than the window for a display device according to Comparative Example, for example, the ratio of the average surface roughness (Ra) and the mean spacing (Sm) of profile irregularities is less than or equal to about 5.0.

### Evaluation IV

The windows for a display device according to Examples 1 to 3 and Comparative Examples 2 and 3 are evaluated for a haze.

The haze is evaluated using a Haze Meter (NDH-5000, Nippon Densoku).

The results are shown in Table 3.

TABLE 3

| | Haze (%) |
|---|---|
| Example 1 | 7.2 |
| Example 2 | 5.0 |
| Example 3 | 1.0 |
| Comparative Example 2 | 12.3 |
| Comparative Example 3 | 10.7 |

Referring to Table 3, it is confirmed that the windows for a display device according to Examples have a lower haze than the windows for a display device according to Comparative Examples.

### Evaluation V

The windows for a display device according to Examples 1 to 3 and Comparative Examples 1 to 3 are evaluated for an abrasion resistance.

The abrasion resistance is evaluated by performing an abrasion rubbing test (Rubbing Test Eraser, Load 500 g), and the surface contact angle is evaluated using a contact angle measurer (DSA100/Kruss).

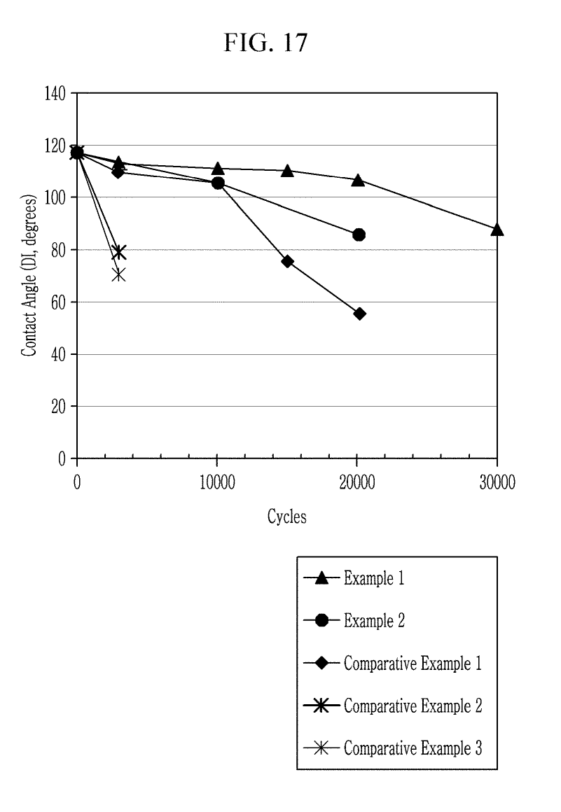

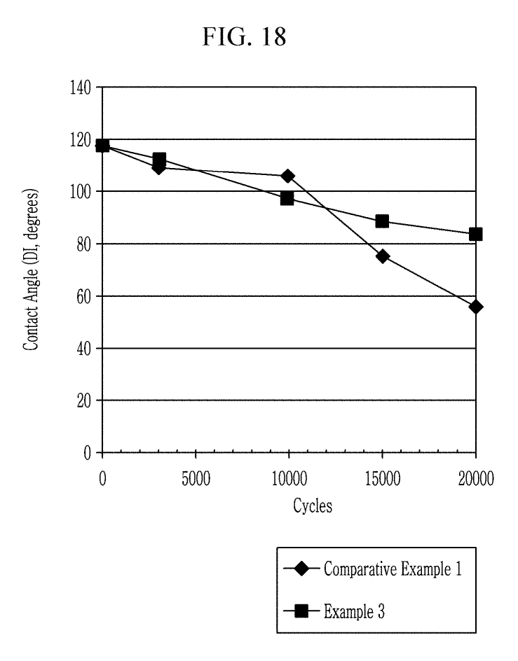

The results are shown in FIGS. 17 and 18.

FIG. 17 is a graph showing a surface contact angle change according to the cycles of abrasion resistance of the windows for a display device according to Examples 1 and 2 and Comparative Examples 1 to 3; and FIG. 18 is a graph showing a surface contact angle change depending upon the cycles of abrasion resistance for the windows for a display device according to Example 3 and Comparative Example 1.

Referring to FIGS. 17 and 18, it is confirmed that the windows for a display device according to Examples 1 to 3 have less contact angle change depending upon the cycles of abrasion resistance than the windows for a display device according to Comparative Examples 1 to 3, for example, it is confirmed that a variation ratio of the surface contact angle after 20,000 cycles is less than or equal to about 40% in the windows for a display device according to Examples 1 to 3.

While this disclosure has been described in connection with what is presently considered to be practical example embodiments, it is to be understood that the inventive concepts are not limited to the disclosed example embodiments, but, on the contrary, is intended to cover various modifications and equivalent arrangements included within the spirit and scope of the appended claims.

What is claimed is:

1. A window for a display device, the window comprising:
a substrate; and
a functional layer on the substrate,
wherein the window includes a plurality of surface irregularities, and
wherein the plurality of surface irregularities are associated with a depth histogram that has a positive skewness and a positive kurtosis.

2. The window of claim 1, wherein
the plurality of surface irregularities of the window are associated with a plurality of surface irregularities of the substrate, and
the functional layer is associated with the plurality of surface irregularities of the substrate.

3. The window of claim 1, wherein
an average surface roughness (Ra) and a mean spacing (Sm) of profile irregularities of the window satisfies Relationship Formula 1:
Ra(nm)/Sm(μm)≤5.0 [Relationship Formula 1]
wherein, in Relationship Formula 1,
Ra denotes an average surface roughness of the window, and
Sm denotes a mean spacing of profile irregularities of the window.

4. The window of claim 3, wherein
the average surface roughness (Ra) of the window satisfies about 5 nm≤Ra≤about 60 nm.

5. The window of claim 3, wherein
the mean spacing (Sm) of profile irregularities of the window satisfies about 5 μm≤Sm≤about 50 μm.

6. The window of claim 1, wherein an average surface roughness (Ra) and a mean spacing (Sm) of profile irregularities of the window satisfy Relationship Formula 2a:
Ra(nm)≤(10−α)/2.0529×Sm(μm) [Relationship Formula 2a]
wherein, in Relationship Formula 2a,
Ra denotes an average surface roughness of the window,
Sm denotes a mean spacing of profile irregularities of the window, and −3.6≤α<0.

7. The window of claim 1, wherein an average surface roughness (Ra) and a mean spacing (Sm) of profile irregularities of the window satisfy Relationship Formula 2c:
Ra(nm)≤(1−α)/2.0529×Sm(μm) [Relationship Formula 2c]
wherein, in Relationship Formula 2c,
Ra denotes an average surface roughness of the window,
Sm denotes a mean spacing of profile irregularities of the window, and
−3.6≤α<0.

8. The window of claim 1, wherein the depth histogram includes a peak of between about 0 nm and about −100 nm.

9. The window of claim 1, wherein the window is associated with a haze of less than or equal to about 10.0.

10. The window of claim 1, wherein the window is associated with a variation ratio of a surface contact angle of less than or equal to about 40% after 20,000 cycles of abrasion rubbing test using 500 g eraser.

11. The window of claim 1, wherein the substrate is a glass substrate.

12. The window of claim 1, wherein the substrate is an etched glass substrate.

13. The window of claim 1, wherein the functional layer includes an anti-fingerprint layer, an anti-reflection layer, an anti-glare layer, an anti-fouling layer, an anti-bacterial layer, a sub-combination thereof, or a combination thereof.

14. A display device, comprising:
a display panel, and
the window of claim 1.

15. The display device of claim 14, wherein the display panel is an organic light emitting display panel or a liquid crystal display panel.

16. The display device of claim 14, further comprising:
a touch screen panel between the display panel and the window.

17. A method of manufacturing a window for a display device, the method comprising:
forming a plurality of surface irregularities on a substrate; and
forming a functional layer on the substrate having the plurality of surface irregularities,
wherein the forming the plurality of surface irregularities includes,
performing primary etching of the substrate subsequently to masking a surface of the substrate, and
performing secondary etching of the primary-etched substrate based on supplying a strong acid thereto,
wherein the plurality of surface irregularities of the substrate are associated with a depth histogram that has a positive skewness and a positive kurtosis.

18. The method of claim 17, wherein the secondary etching is performed longer than the primary etching.

19. The method of claim 17, wherein the forming of the functional layer is performed based on a solution process or a deposition.
